(19) United States
(12) Patent Application Publication
(10) Pub. No.: US 2006/0043433 A1
(43) Pub. Date: Mar. 2, 2006

(54) Light-emitting diode

(75) Inventor: Yasuhiko Matsushita, Tottori-Shi (JP)

Correspondence Address: MCDERMOTT WILL & EMERY LLP, 600 13TH STREET, N.W., WASHINGTON, DC, 20005-3096, US

(73) Assignee: SANYO ELECTRIC CO,. LTD., Osaka (JP)

(21) Appl. No.: 10/542,542

(22) PCT Filed: Jun. 30, 2004
(86) PCT No.: PCT/JP04/09182

§ 371 Date: Jul. 18, 2005

(30) Foreign Application Priority Data
Jul. 18, 2003 (JP) 2003-276610

(51) Int. Cl. H01L 31/112

(52) U.S. Cl. 257/257

(57) ABSTRACT

A light-emitting diode 10A has a light-emitting element 11a fixed to a leadframe 30 with a conductive adhesive material 20, the light-emitting element 11a having a semiconductor layer 9 including a light-emitting layer 16 laid on a first surface 12a of a translucent substrate 12, a second surface 12b thereof facing away from the first surface 12a being used as a light emission observation surface. A side surface of the semiconductor layer 9 is an inclined surface inclined relative to the first surface 12a, and an angle θ between a normal “a” to the inclined surface and a crystal surface on which the light-emitting layer 16 grows is equal to an angle at which light emitted by the light-emitting layer 16 is totally reflected toward the translucent substrate 12.

### TECHNICAL FILED

The present invention relates to a light-emitting diode having a light-emitting element composed of a semiconductor layer laid on top of a translucent substrate.

### BACKGROUND ART

One of the challenges associated with various light-emitting devices such as blue light-emitting diodes and blue laser diodes is how to increase the efficiency with which light is extracted from a light-emitting element. The light emission efficiency of, in particular, white light-emitting diodes has been improving year after year, almost doubling every two years. Even with this fast improvement, it is said it will take another several years to overtake the light emission efficiency, 60 lm/W, of fluorescent lamps commonly used in households.

On the other hand, in light-emitting diodes currently being developed, about 80% of the light generated is wasted. The part of the light that does not go out of the light-emitting element undergoes repeated multiple reflection inside the element, and meanwhile converts into heat energy, which then dissipates.

Thus, aiming at higher light emission efficiency, research and development have been eagerly conducted. One way of increasing light emission efficiency pays attention to the material of the light-emitting element. Specifically, in a white light-emitting diode composed of a blue light-emitting element and a fluorescent material that converts blue light into yellow light, defects in the crystal of the light-emitting element is reduced and thereby the quality of the crystal is enhanced. This makes it more difficult for electric energy to be converted into heat energy in the light-emitting layer in the light-emitting element, and thus helps increase light energy.

Another way involves changing the shape of the light-emitting element. The light generated in the light-emitting layer undergoes multiple reflection inside the light-emitting element before going out of it. This multiple reflection is reduced and thereby light emission efficiency is increased. For example, a sapphire substrate is so processed as to reduce reflection at sapphire substrate interfaces. Alternatively, a sapphire substrate is peeled off to form a reflective layer, by the use of which the direction of the light traveling toward the bottom surface is changed. Such processing of a sapphire substrate, however, is still under research, and it is expected it will take several years to put that into practical use.

On the other hand, Patent Publication 1 discloses a method for improving light emission efficiency without such troublesome processing of a sapphire substrate but through simple shape change. In this light-emitting diode, the side surfaces of the light-emitting element are cut at an acute angle from the light emission observation surface side of the translucent substrate to the light-emitting layer (of a gallium nitride compound). The blue light emitted from the gallium nitride compound, in particular the blue light emitted from around the side surfaces of the light-emitting element, is reflected on the translucent substrate so as to be effectively extracted to the light emission observation surface. This light-emitting diode does not require a cup-shaped leadframe as is conventionally required by this type of light-emitting diode. This helps enhance productivity, and permits a ceramic substrate to be used as a leadframe and as a support member.

Moreover, in Patent Publication 1, it is stated that, from the production engineering point of view, it is impossible to apply this light-emitting diode to a light-emitting diode having a cup-shaped leadframe. Specifically, with a cup-shaped leadframe, a compound semiconductor light-emitting element (for example, a gallium nitride compound semiconductor light-emitting element) so structured as to have a translucent substrate at the top and an electrode at the bottom cannot be assembled.

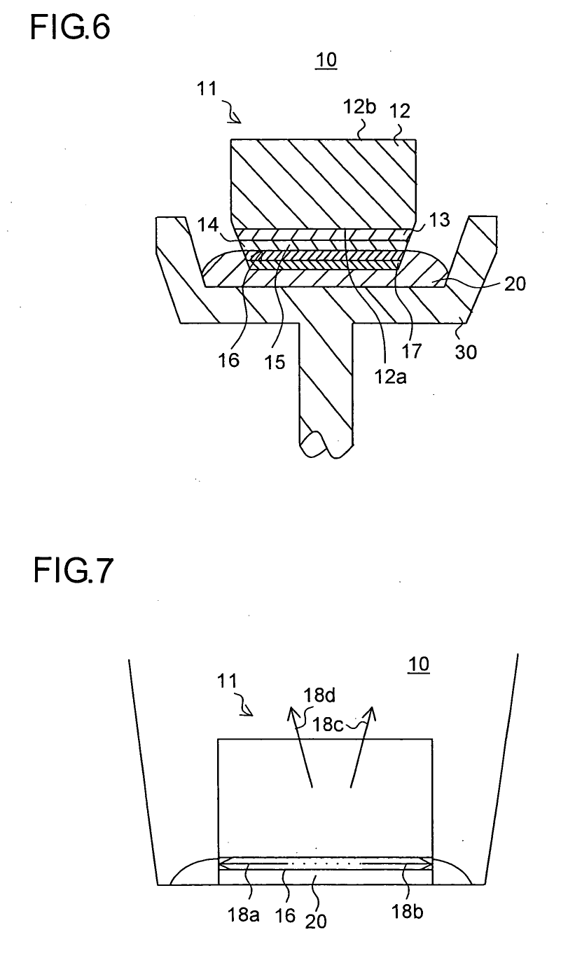

On the other hand, FIG. 6 is a sectional view of a conventional light-emitting diode employing a cup-shaped leadframe. The light-emitting diode 10 has a light-emitting element (hereinafter referred to as the “LED chip”) 11 provided on top of a cup-shaped leadframe 30. The LED chip 11 has a translucent substrate 12 formed of insulating sapphire, and on a first surface 12a thereof are laid, via a buffer layer 13, a first-conductivity-type semiconductor layer 14 and a second-conductivity-type semiconductor layer 15. Between the first-conductivity-type semiconductor layer 14 and the second-conductivity-type semiconductor layer 15 is formed a light-emitting layer 16. A second surface 12b facing away from the first surface 12a is used as a light emission observation surface.

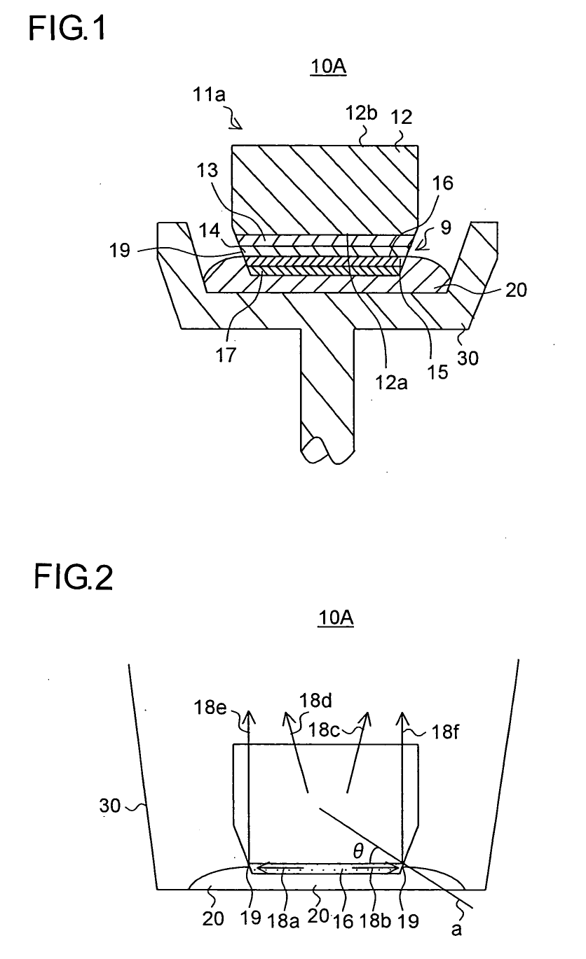

Moreover, the LED chip 11 has an electrode 17 electrically connected onto the leadframe 30 with conductive adhesive 20. Although not illustrated, n- and p-electrodes are laid while being appropriately insulated from one another. The LED chip 11 is coupled to the leadframe 30 with the conductive adhesive 20 somewhat bulging onto the sides surfaces of the LED chip 11. Typically used as the conductive adhesive 20 is a conductive material that exhibits adhesion.
Patent Publication 1: U.S. Pat. No. 2,964,822 (FIG. 1; pages 2 to 3)

### DISCLOSURE OF THE INVENTION

### Problems to be Solved by the Invention

FIG. 7 is a sectional view schematically showing the paths of light beams inside the LED chip 11. In the light-emitting diode 10, light is emitted from the light-emitting layer 16 to above the LED chip 11 (indicated by arrows 18c and 18d) and toward the side surfaces (indicated by arrows 18a and 18b). Of these emitted light beams 18a to 18d, those emitted toward the side surfaces, namely the emitted light beams 18a and 18b, are shielded by conductive adhesive 20a and 20b. Thus, the emitted light beams 18a and 18b are not used effectively, lowering the light emission intensity of the entire chip.

In view of the conventionally encountered problems discussed above, it is an object of the present invention to provide a light-emitting diode that offers enhanced light emission efficiency through effective use of the light emitted from the side surfaces of a light-emitting element.

### Means for Solving the Problem

To achieve the above object, according to the present invention, in a light-emitting diode having a light-emitting element fixed to a leadframe with a conductive adhesive material, the light-emitting element having a semiconductor layer including a light-emitting layer laid on a first surface of a translucent substrate of which a second surface facing away from the first surface is used as a light emission observation surface,

a side surface of the semiconductor layer is an inclined surface inclined relative to the first surface, and the angle between a normal to the inclined surface and the crystal surface on which the light-emitting layer grows is equal to the angle at which the light emitted by the light-emitting layer is totally reflected toward the translucent substrate.

Moreover, according to the present invention, in the light-emitting diode structured as described above, the semiconductor layer has a first-conductivity-type semiconductor layer and a second-conductivity-type semiconductor layer formed by laying a first-conductivity-type compound semiconductor and a second-conductivity-type compound semiconductor in this order from the translucent substrate side so that the first-conductivity-type semiconductor layer and the second-conductivity-type semiconductor layer are adjacent to each other with the light-emitting layer sandwiched in between, with a vertical hole formed so deep as to penetrate the translucent substrate and reach the first-conductivity-type semiconductor layer but not to reach the second-conductivity-type semiconductor layer, and with a conductive material formed along the vertical hole so as to conduct to the first-conductivity-type semiconductor layer.

Moreover, according to the present invention, in the light-emitting diode structured as described above, the semiconductor layer has a first-conductivity-type semiconductor layer and a second-conductivity-type semiconductor layer formed by laying a first-conductivity-type compound semiconductor and a second-conductivity-type compound semiconductor in this order from the translucent substrate side so that the first-conductivity-type semiconductor layer and the second-conductivity-type semiconductor layer are adjacent to each other with the light-emitting layer sandwiched in between, with an insulating member filling an opening formed in the second-conductivity-type semiconductor layer, with a vertical hole formed above the opening so as to penetrate the translucent substrate and the first-conductivity-type semiconductor layer, and with a conductive material formed along the inner wall surface of the vertical hall so as to conduct to the first-conductivity-type semiconductor layer.

Moreover, according to the present invention, in the light-emitting diode structured as described above, the vertical hole is closed by a pad electrode formed on the second surface of the translucent substrate.

Moreover, according to the present invention, in the light-emitting diode structured as described above, the vertical hole is increasingly small with increasing depth.

Moreover, according to the present invention, in the light-emitting diode structured as described above, the conductive material is translucent.

Moreover, according to the present invention, in the light-emitting diode structured as described above, the angle is in a range from 40° to 50°.

Moreover, according to the present invention, in the light-emitting diode structured as described above, the inclined surface is coated with an insulating film.

### ADVANTAGES OF THE INVENTION

According to the present invention, the angle between a normal to the side surface, on which the light-emitting layer is exposed and which is formed as an inclined surface, of the light-emitting layer and the crystal surface on which the light-emitting layer grows is made equal to the angle at which the light emitted from the light-emitting layer is totally reflected toward the translucent substrate. Thus, the light that travels from the light-emitting layer toward the side surface of the light-emitting element has its course changed so as to be emitted through the light emission observation surface. Thus, the light emitted from the light-emitting layer is not shielded by the adhesive material, but all the light is emitted through the light emission observation surface. This enhances the light emission output of the light-emitting element.

Moreover, according to the present invention, there are provided a vertical hole so deep as to reach the first-conductivity-type semiconductor layer but not to reach the second-conductivity-type semiconductor layer and a conductive material formed along the vertical hole so as to conduct to the first-conductivity-type semiconductor layer. Thus, an electrode that conducts to the conductive material and via which a voltage is applied to the semiconductor layer can be formed on the light emission observation surface of the translucent substrate. This permits electrodes to be arranged separately on the first-surface and second-surface sides of the translucent substrate. Thus, it is possible to alleviate the shielding of light by the electrodes and thereby enhance light extraction efficiency. Moreover, wire-bonding for electrode-to-lead connection needs to be performed only at one spot. This greatly enhances assembly workability.

Moreover, according to the present invention, a vertical hole is formed to penetrate the thin first-conductivity-type semiconductor layer. This makes the light-emitting diode easy to fabricate.

Moreover, according to the present invention, a pad electrode having an area larger than the cross-sectional area of the vertical hole is provided. This permits easy wire-bonding of a lead.

Moreover, according to the present invention, the vertical hole is made increasingly small with increasing depth. This makes it easy to form a conductive material with a predetermined thickness on the inner surface of the vertical hole by vapor deposition or sputtering.

Moreover, according to the present invention, the conductive material is translucent. This reduces the absorption of light inside the vertical hole, and thus permits the light emitted by the light-emitting layer to be extracted to the outside effectively without loss.

Moreover, according to the present invention, the side surface of the semiconductor layer is given an inclination of 40° to 50°. This makes it easy to realize a light-emitting diode in which total reflection is achieved on that side surface.

Moreover, according to the present invention, the inclined side surface of the semiconductor layer is coated with an insulating layer. This helps prevent short-circuiting of the semiconductor layer via the conductive adhesive that may occur when the light-emitting element is fixed on the leadframe with the conductive adhesive.

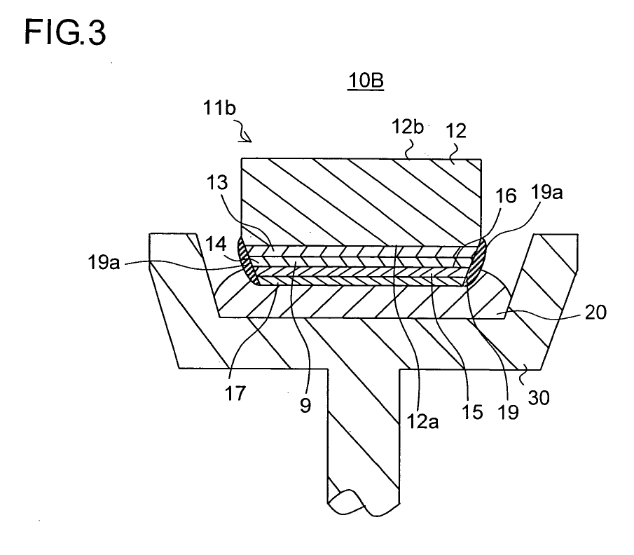

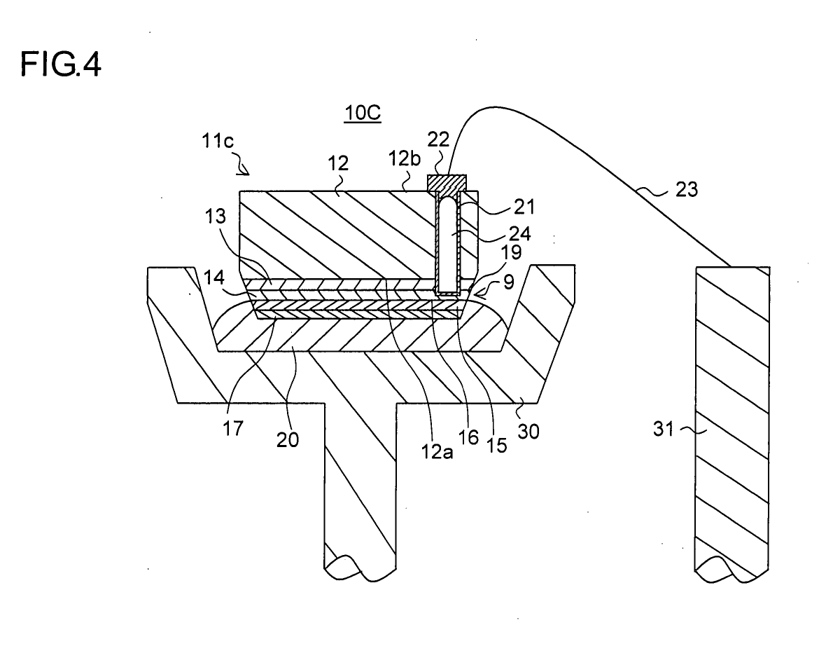

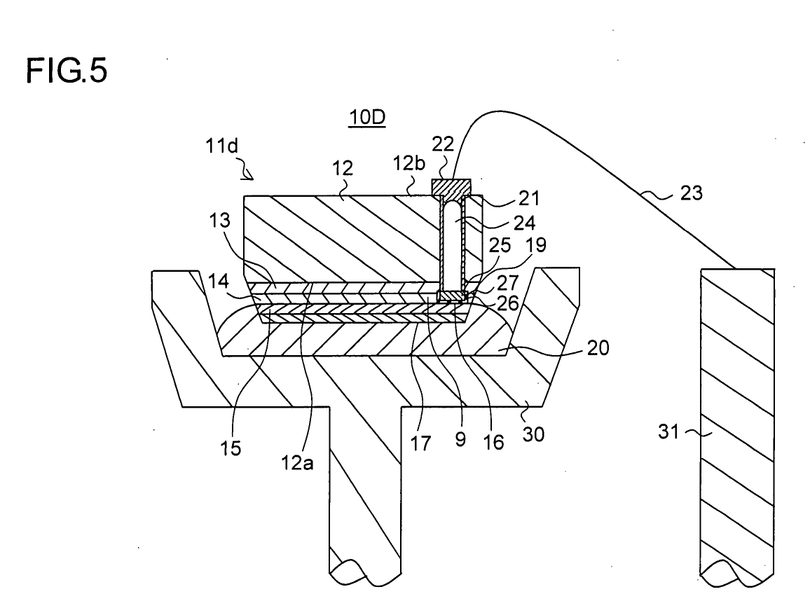

### BRIEF DESCRIPTION OF DRAWINGS

[FIG. 1] A sectional view showing the light-emitting diode of a first embodiment of the invention.

[FIG. 2] A sectional view schematically showing the paths of light beams inside the element in the light-emitting diode of the first embodiment of the invention.

[FIG. 3] A sectional view showing the light-emitting diode of a second embodiment of the invention.

[FIG. 4] A sectional view showing the light-emitting diode of a third embodiment of the invention.

[FIG. 5] A sectional view showing the light-emitting diode of a fourth embodiment of the invention.

[FIG. 6] A sectional view showing a conventional light-emitting diode.

[FIG. 7] A sectional view schematically showing the paths of light beams inside the element in the conventional light-emitting diode.

### LIST OF REFERENCE SYMBOLS

9 Semiconductor Layer

10, 10A to 10D Light-Emitting Diode

11, 11a to 11d Light-Emitting Element (LED Chip)

12 Translucent Substrate

13 Buffer Layer

14 First-Conductivity-Type Semiconductor Layer

15 Second-Conductivity-Type Semiconductor Layer

16 Light-Emitting Layer

17 Electrode

18a to 18d Emitted Light Beam

19 Inclined Surface

19a Insulating Film

20 Conductive Adhesive

21 Conductive Material

22 Pad Electrode

24 Vertical Hole

26 Insulating Member

27 Opening

30 Leadframe

31 Lead Electrode

### BEST MODE FOR CARRYING OUT THE INVENTION

Hereinafter, embodiments of the present invention will be described with reference to the drawings. For the sake of convenience, such parts as find their counterparts in FIGS. 6 and 7 described earlier are identified with common reference symbols. It should be understood that the present invention may be implemented in any manner other than specifically shown in the drawings. FIG. 1 is a sectional view showing the light-emitting diode of a first embodiment of the invention.

The light-emitting diode 10A has an LED chip 11a provided on top of a cup-shaped leadframe 30. The LED chip 11a has a translucent substrate 12 formed of insulating sapphire, and on a first surface 12a of the sapphire substrate 12 is formed, via a butter layer 13, a semiconductor layer 9. The semiconductor layer 9 is composed of a first-conductivity-type semiconductor layer 14 formed of one of p- and n-type semiconductors and a second-conductivity-type semiconductor layer 15 formed of the other of the p- and n-type semiconductors. Between the first-conductivity-type semiconductor layer 14 and the second-conductivity-type semiconductor layer 15 is formed a light-emitting layer 16, and an electrode 17 is formed on the second-y-type conductivity-type semiconductor layer 15. Facing away from the first surface 12a is a semiconductor surface 12b, which is used as a light emission observation surface.

The LED chip 11a is fixed to the leadframe 30 with conductive adhesive 20, and the electrode 17 is electrically connected to the leadframe 30. Although not illustrated, n- and p-electrodes that conduct to the first- and second-conductivity-type semiconductor layers 14 and 15 are laid while being insulated from each other. The LED chip 11a is coupled to the leadframe 30 with the conductive adhesive 20 somewhat bulging onto the side surfaces of the LED chip 11a. Typically used as the leadframe 30 is a conductive material that exhibits adhesion.

The side surfaces of the semiconductor layer 9 are formed as inclined surfaces 19 that are inclined relative to the first surface 12a of the translucent substrate 12. The inclined surfaces 19 are so inclined that, on both end surfaces where the light-emitting layer 16 is exposed, the higher up the semiconductor layer 9, the further out relative to the LED chip 11a. Thus, the semiconductor layer 9 becomes narrower the farther away from the translucent substrate 12.

The inclined surfaces 19 are formed, in the course of the fabrication process of the semiconductor layer 9, under specifically selected dry-etching conditions. Specifically, an appropriate inclination is given to the end surfaces of the mask used in dry-etching. By a method that permits the inclination of the end surfaces of the mask to be taken over by the etched end surfaces of the crystal, the inclined surfaces 19 can be formed.

Alternatively, the inclined surfaces 19 may be formed by forming grooves with a dicing blade having a tapered edge. When this is performed, dicing damages the light-emitting layer 16, but the crystal defects resulting from the damage can be removed by dry-etching or the like.

FIG. 2 is a sectional view schematically showing the paths of light beams inside the LED chip 11a. The angle θ between a normal “a” to the inclined surfaces 19 and the crystal surface on which the light-emitting layer 16 grows is made greater than the critical angle of the light 18a and 18b that falls on the inclined surfaces 19 from the inclined surfaces 19. As a result, all the light 18a and 18b emitted from the light-emitting layer 16 is reflected toward the translucent substrate 12 so as to be totally reflected to the interior of the LED chip 11a. Setting the angle θ in the range from 40° to 50° guarantees total reflection, and makes the inclined surfaces 19 easy to form.

As a result of the side surfaces, on which the light-emitting layer 16 is exposed, of the semiconductor layer 9 being formed as inclined surfaces 19, the light 18e and 18f that travels from the light-emitting layer 16 to the side surfaces of the light-emitting layer 16 has its course changed so as to be emitted through the light emission observation surface. Thus, no light is shielded by an adhesive material as experienced conventionally. Instead, all the light emitted from the light-emitting layer 16 is reflected from the inclined surfaces 19, enhancing the light emission output of the LED chip 11a.

It is particularly preferable that the structure described above be applied to a blue light-emitting diode having a light-emitting layer 16 formed of gallium nitride compound. This permits the blue light emitted with low light emission efficiency to be totally reflected on the inclined surfaces 19 so as to be extracted through the light emission observation surface. In this way, it is possible to greatly enhance the light emission output.

FIG. 3 is a sectional view showing the light-emitting diode of a second embodiment of the invention. For the sake of convenience, such parts as are found also in the first embodiment shown in FIGS. 1 and 2 described above are identified with common reference symbols. In the light-emitting diode 10B of this embodiment, the inclined surfaces 19 are coated with an insulating film 19a. In other respects, the light-emitting diode 10B is the same as the light-emitting diode 10A of the first embodiment.

In the light-emitting diode 10B, an LED chip 11b having inclined surfaces 19 is fixed on top of a cup-shaped leadframe 30 with conductive adhesive 20. Here, even if the conductive adhesive 20 somewhat bulges onto the side surfaces of the LED chip 11 b, the insulating film 19a prevents short-circuiting resulting from the conductive adhesive 20 and the first-conductivity-type semiconductor layer 14 making contact with each other.

FIG. 4 is a sectional view showing the light-emitting diode of a third embodiment of the invention. For the sake of convenience, such parts as are found also in the first embodiment shown in FIGS. 1 and 2 described above are identified with common reference symbols. In the light-emitting diode 10C of this embodiment, the LED chip 11c has a vertical hole 24 formed therein so as to extend vertically. In other respects, the light-emitting diode 10C is the same as the light-emitting diode 10A of the first embodiment.

The vertical hole 24 is formed by laser irradiation or the like in a peripheral portion, for example in one of the four corners, of the translucent substrate 12. The vertical hole 24 is made so deep as to penetrate the translucent substrate 12 and reach the first-conductivity-type semiconductor layer 14 but not to reach the second-conductivity-type semiconductor layer 15. The vertical hole 24 is several tens of μm across, and is formed in a cylindrical or conical shape.

The vertical hole 24 is used as an electrical path that runs vertically inside the LED chip 11c. To form the electrical path, a conductive material 21 is formed along the inner surface of the vertical hole 24 by vapor deposition, sputtering, or the like. Forming the vertical hole 24 in such a way that its cross-sectional area decreases with increasing depth makes it easy to form the conductive material 21 with a predetermined thickness on the inner surface of the vertical hole 24.

The vertical hole 24 is closed with a pad electrode 22 having an area larger than the opening formed on the second surface 12b of the translucent substrate 12. This permits the pad electrode 22 to be electrically connected to the first-conductivity-type semiconductor layer 14 via the conductive material 21. The pad electrode 22 is connected to a lead electrode 31 via a wire-bonded wire 23. Forming the whole or a part of the conductive material 21 with a translucent material helps alleviate the shielding of light by the conductive material 21 and thereby prevent the diminishing of the light emission output.

In the light-emitting diode 11C structured as described above, when a predetermined voltage is fed between the electrode formed by the leadframe 30 and the lead electrode 31, a path is formed from the leadframe 30 through the conductive adhesive 20, the electrode 17, the second-conductivity-type semiconductor layer 15, the light-emitting layer 16, the first-conductivity-type semiconductor layer 14, the conductive material 21, the pad electrode 22, the wire 23, to the lead electrode 31, causing the light-emitting layer 16 to emit light.

In this embodiment, the same effects as obtained in the first embodiment are obtained. In addition, owing to the structure involving a reduced number of electric-field-concentrated spots in the current path, it is possible to enhance the electrostatic withstand voltage of the light-emitting diode 11C. Moreover, whereas a conventional light-emitting diode typically has electrodes, between which to apply a voltage, arranged on one side, namely the light emission observation surface side, of a translucent substrate 12, the light-emitting diode 11C has electrodes arranged separately on the first and second surface 12a and 12b sides of the translucent substrate 12. This helps reduce the shielding of light by the electrodes and thereby enhance the light extraction efficiency. Moreover, wire-bonding needs to be performed only at one spot. This enhances the assembly workability of the light-emitting diode 11C. The inclined surfaces 19 may be coated with an insulating film 19a (see FIG. 3) like the one used in the second embodiment.

FIG. 5 is a sectional view showing the light-emitting diode of a forth embodiment of the invention. For the sake of convenience, such parts as are found also in the third embodiment shown in FIG. 4 described above are identified with common reference symbols. In the light-emitting diode 10D of this embodiment, the LED chip 11d has an opening 27 formed in the second-conductivity-type semiconductor layer 15. The vertical hole 24 is formed above the opening 27 so as to penetrate the translucent substrate 12 and the first-conductivity-type semiconductor layer 14. In other respects, the light-emitting diode 10D is the same as the light-emitting diode 10C of the third embodiment.

The opening 27 is formed by etching or the like after the formation of the second-conductivity-type semiconductor layer 15. The vertical hole 24 is formed by laser irradiation or the like, and is so formed as to penetrate the translucent substrate 12 and the first-conductivity-type semiconductor layer 14 and reach the opening 27. A conductive material 21 is formed along the inner wall of the vertical hole 24 by sputtering or the like. This permits the conductive material 21 to conduct to the first-conductivity-type semiconductor layer 14.

Moreover, inside the opening 27 is formed a conductive film 25 that covers the vertical hole 24. The conductive film 25 ensures that the conductive material 21 and the first-conductivity-type semiconductor layer 14 conduct to each other. The conductive film 25 is covered from around by an insulating member 26 that fills the opening 27. This prevents short-circuiting between the first- and second-conductivity-type semiconductor layers 14 and 15.

In this embodiment, the same effects obtained in the third embodiment shown in FIG. 3 described earlier are obtained. In addition, whereas in the light-emitting diode 10C of the third embodiment it is difficult to control laser irradiation because the vertical hole 24 needs to be formed so as not to penetrate the first-conductivity-type semiconductor layer 14, in this embodiment it is easy to control laser irradiation because the opening 27 is formed beforehand in the second-conductivity-type semiconductor layer 15 and thereafter the vertical hole 24 is formed to penetrate the first-conductivity-type semiconductor layer 14.

As discussed above in connection with practical examples of the present invention, light-emitting diodes as described above according to the present invention are applicable to well-known light-emitting diodes in general that have a light-emitting element fixed to a leadframe 30 with a conductive material 21 wherein the light-emitting element has a semiconductor layer 9 including a light-emitting layer 16 laid on a first surface 12a of a translucent substrate 12 of which a second surface 12b facing away from the first surface 12a is used as a light emission observation surface.

In particular, since blue light-emitting diodes having a light-emitting layer 16 formed of a gallium nitride compound on top of a translucent substrate 12 have low light emission efficiency, applying the present invention to them helps greatly enhance their light emission output.

Industrial Applicability

The present invention can be applied to light-emitting diodes having a cup-shaped leadframe to enhance their light emission output. The present invention is particularly suitable for blue light-emitting diodes having low light emission efficiency.

1. A light-emitting diode having a light-emitting element fixed to a leadframe with a conductive adhesive material, the light-emitting element having a semiconductor layer including a light-emitting layer laid on a first surface of a translucent substrate, of which a second surface facing away from the first surface is used as a light emission observation surface,
wherein a side surface of the semiconductor layer is an inclined surface inclined relative to the first surface, and an angle between a normal to the inclined surface and a crystal surface on which the light-emitting layer grows is equal to an angle at which light emitted by the light-emitting layer is totally reflected toward the translucent substrate.

2. The light-emitting diode of claim 1, wherein the semiconductor layer has a first-conductivity-type semiconductor layer and a second-conductivity-type semiconductor layer formed by laying a first-conductivity-type compound semiconductor and a second-conductivity-type compound semiconductor in this order from a translucent substrate side so that the first-conductivity-type semiconductor layer and the second-conductivity-type semiconductor layer are adjacent to each other with the light-emitting layer sandwiched in between, with a vertical hole formed so deep as to penetrate the translucent substrate and reach the first-conductivity-type semiconductor layer but not to reach the second-conductivity-type semiconductor layer, and with a conductive material formed along the vertical hole so as to conduct to the first-conductivity-type semiconductor layer.

3. The light-emitting diode of claim 1, wherein the semiconductor layer has a first-conductivity-type semiconductor layer and a second-conductivity-type semiconductor layer formed by laying a first-conductivity-type compound semiconductor and a second-conductivity-type compound semiconductor in this order from a translucent substrate side so that the first-conductivity-type semiconductor layer and the second-conductivity-type semiconductor layer are adjacent to each other with the light-emitting layer sandwiched in between, with an insulating member filling an opening formed in the second-conductivity-type semiconductor layer, with a vertical hole formed above the opening so as to penetrate the translucent substrate and the first-conductivity-type semiconductor layer, and with a conductive material formed along an inner wall surface of the vertical hall so as to conduct to the first-conductivity-type semiconductor layer.

4. The light-emitting diode of claim 2, wherein the vertical hole is closed by a pad electrode formed on the second surface of the translucent substrate.

5. The light-emitting diode of claim 2, wherein the vertical hole is increasingly small with increasing depth.

6. The light-emitting diode of claim 2, wherein the conductive material is translucent.

7. The light-emitting diode of claim 1, wherein the angle is in a range from 40° to 50°.

8. The light-emitting diode of claim 1, wherein the inclined surface is coated with an insulating film.

9. The light-emitting diode of claim 1, wherein the semiconductor layer is formed of a gallium nitride compound.
